(19) United States
(12) Patent Application Publication
(10) Pub. No.: US 2025/0063789 A1
(43) Pub. Date: Feb. 20, 2025

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Fu-Hsiang SU, Zhubei City (TW); Ping-Chun WU, Hsinchu City (TW); Je-Wei HSU, Hsinchu City (TW); Hong-Chih CHEN, Changhua County (TW); Chia-Hao KUO, Taoyuan City (TW); Shih-Hsun CHANG, Hsinchu (TW)

(73) Assignee: Taiwan Semiconductor Manufacturing Company, Ltd., Hsinchu (TW)

(21) Appl. No.: 18/449,911

(22) Filed: Aug. 15, 2023

(51) Int. Cl. H01L 29/66; H01L 21/8234; H01L 27/088; H01L 29/06; H01L 29/423; H01L 29/775; H01L 29/786

(52) U.S. Cl. CPC H01L 29/66545; H01L 21/823418; H01L 21/823475; H01L 21/823481; H01L 27/088; H01L 29/0673; H01L 29/42392; H01L 29/66439; H01L 29/6656; H01L 29/775; H01L 29/78696

(57) ABSTRACT

A method for forming a semiconductor device structure includes forming nanostructures over a substrate. The method also includes forming a gate structure wrapped around the nanostructures. The method also includes forming source/drain epitaxial structures over opposite sides of the nanostructures. The method also includes forming a first interlayer dielectric structure over the source/drain epitaxial structures. The method also includes removing the first interlayer dielectric structure. The method also includes forming a recess in the source/drain epitaxial structures. The method also includes forming a silicide structure in the recess. The method also includes forming a second interlayer dielectric structure over the silicide structure.

### BACKGROUND

Semiconductor devices are used in a variety of electronic applications, such as personal computers, cell phones, digital cameras, and other electronic equipment. Semiconductor devices are typically fabricated by sequentially depositing insulating or ILD structures, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure which can extend around the channel region providing access to the channel on two or four sides. GAA devices are compatible with conventional complementary metal-oxide-semiconductor (CMOS) processes.

However, the integration of fabrication of the GAA features around the nanowire can be challenging. While the current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-IF are perspective representations of various stages of forming a semiconductor device structure, in accordance with some embodiments of the disclosure.

FIGS. 1G, 1G-1, 1H, 1H-1, 1I, 1I-1, 1J, 1J-1, 1K, 1K-1, 1L, 1L-1, 1M, 1M-1, 1N, 1N-1, 1O, 1O-1, 1P and 1P-1 are cross-sectional representations of various stages of forming a semiconductor device structure, in accordance with some embodiments of the disclosure.

FIG. 2 is a cross-sectional representation of a semiconductor device structure, in accordance with some embodiments of the disclosure.

FIG. 3 is a cross-sectional representation of a semiconductor device structure, in accordance with some embodiments of the disclosure.

FIG. 4 is a cross-sectional representation of a semiconductor device structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The nanostructure transistor (e.g. nanosheet transistor, nanowire transistor, multi-bridge channel, nano-ribbon FET, forksheet structures, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures.

Embodiments for forming a semiconductor device structure are provided. The method for forming the semiconductor device structure may include forming a silicide structure in the source/drain epitaxial structures. With larger silicide structure, the resistance may be lowered. In addition, the bottom nanostructures may be enhanced by the silicide structure. The process window may be enlarged, and the leakage current may be reduced.

The semiconductor device structure may include various active devices. For example, the semiconductor device structure may include gate all around (GAA) structures. The semiconductor device structure may also include channel structures such as nanosheet structures, forksheet structures, and CFET structures. The semiconductor device structure may also include FinFET structures, or Si and SiGe planar transistors.

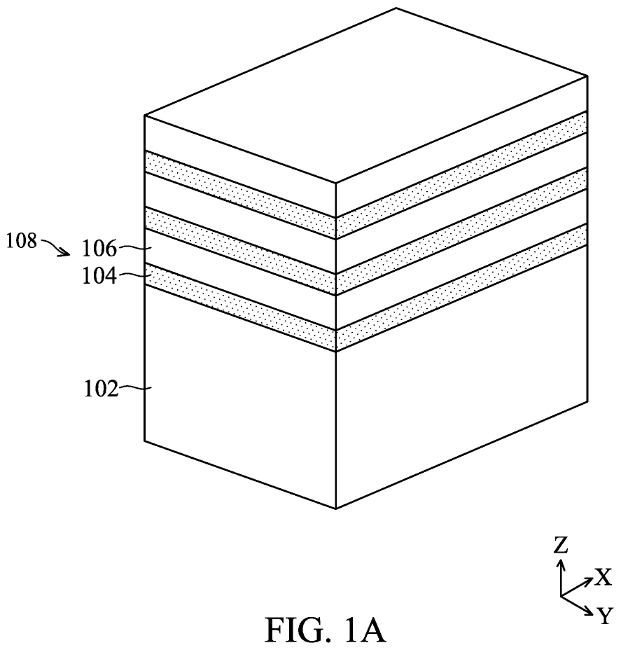

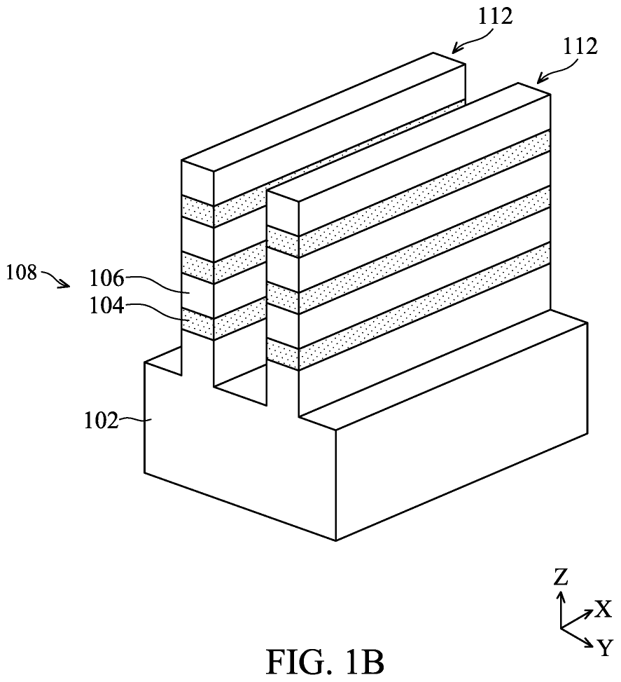

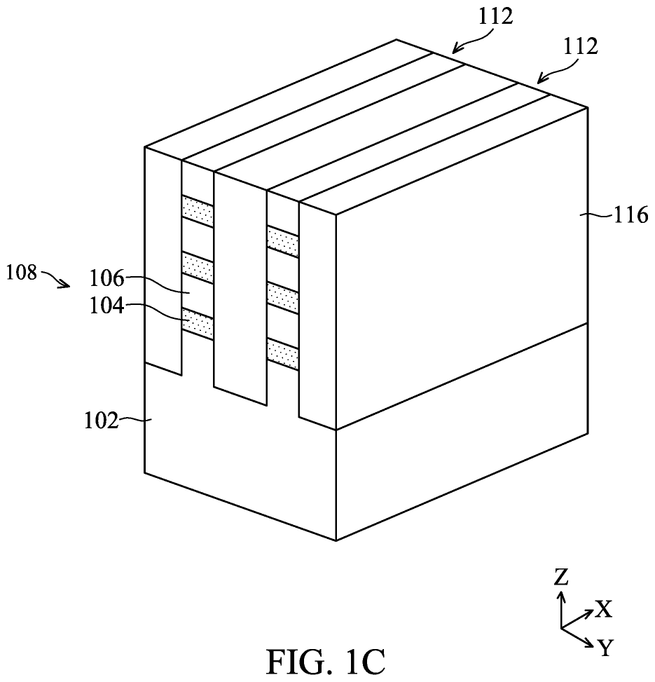

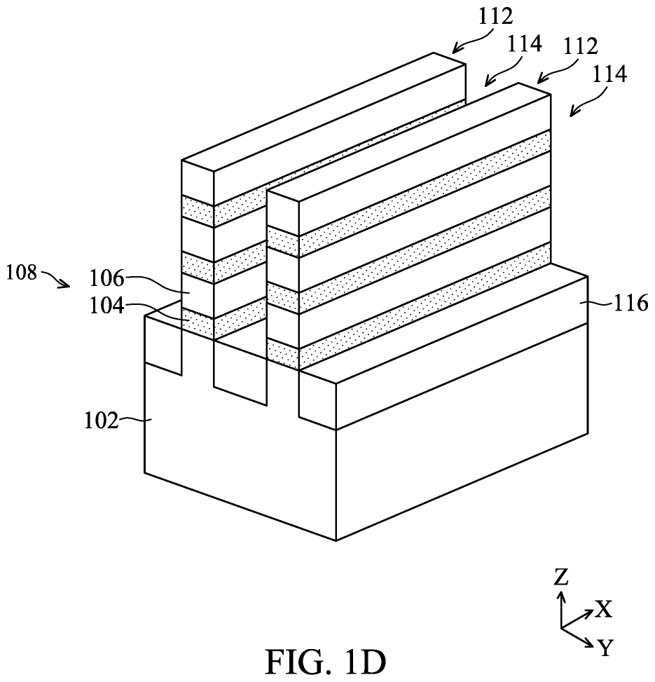

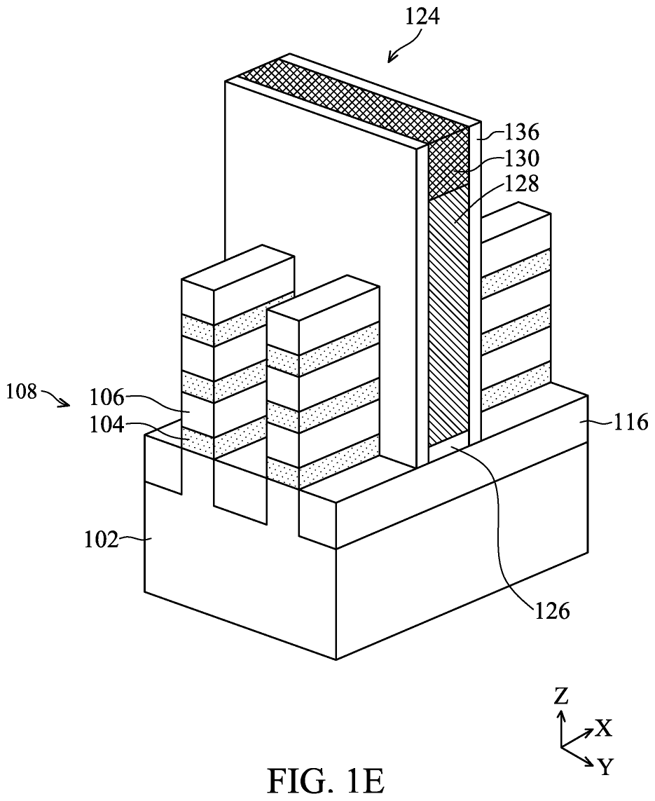

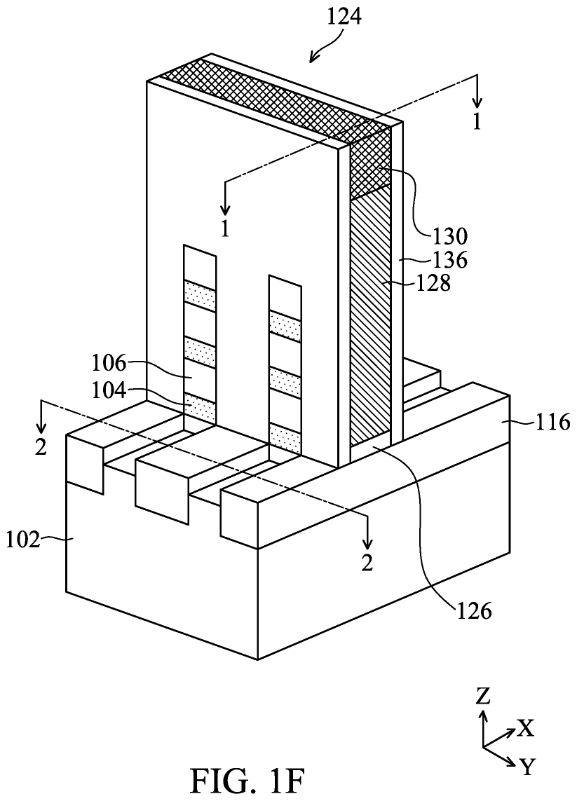

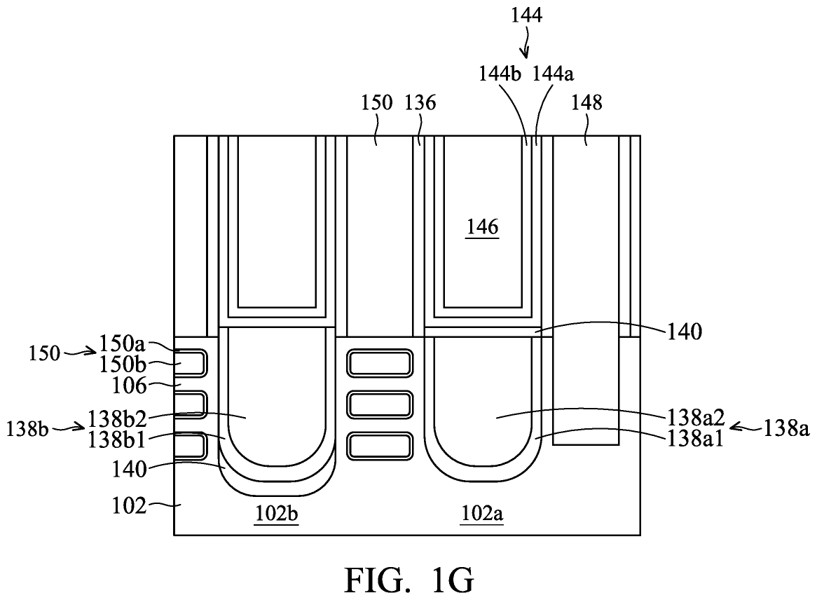

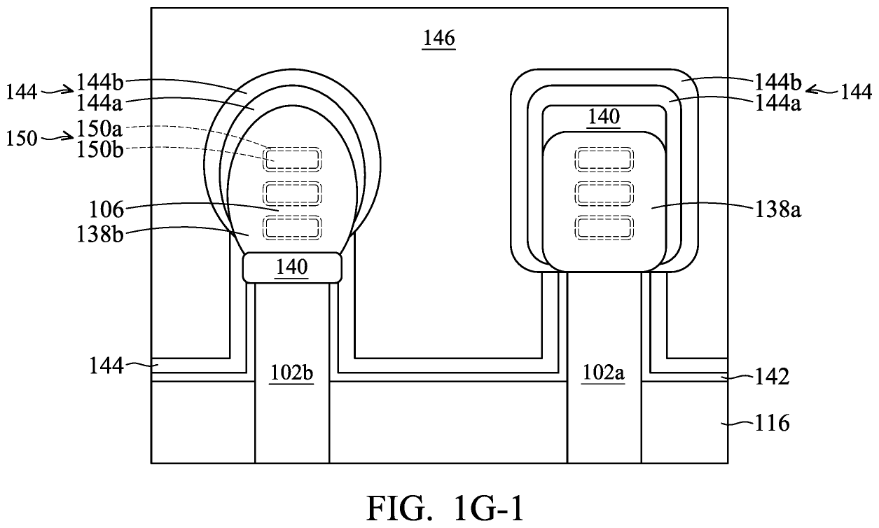

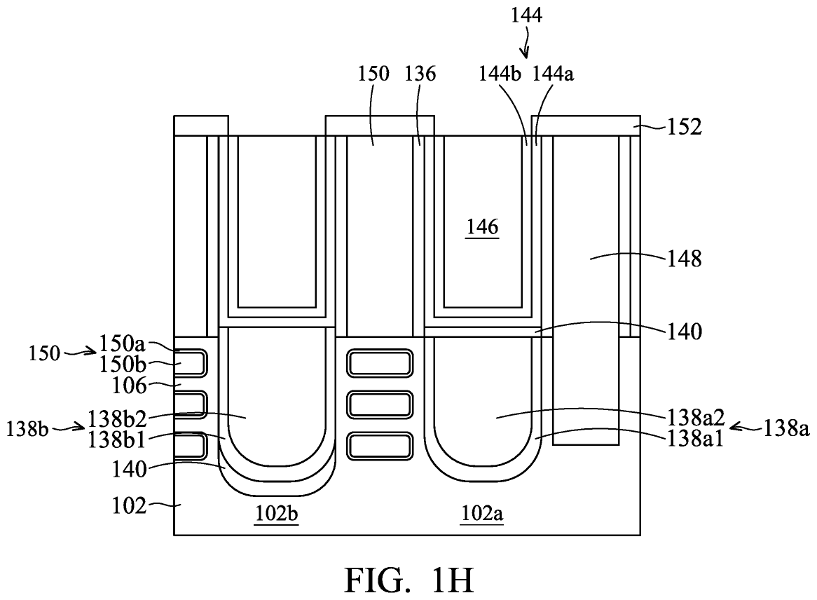

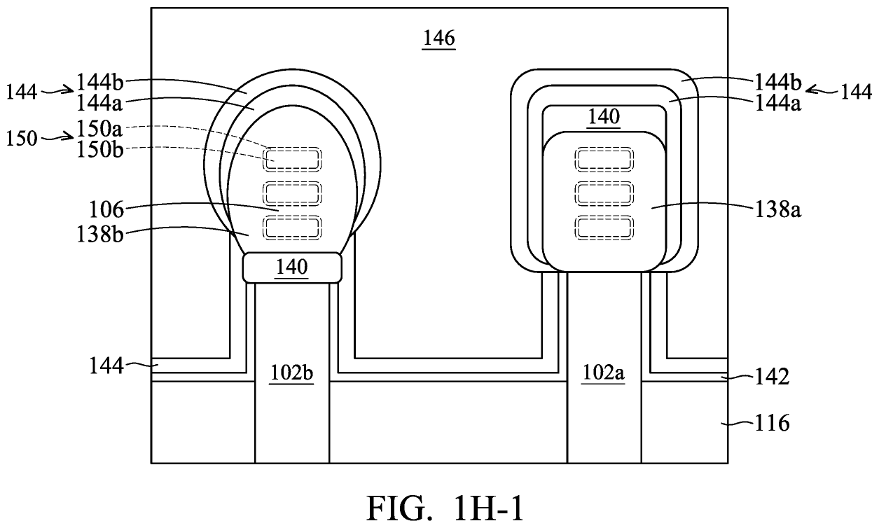

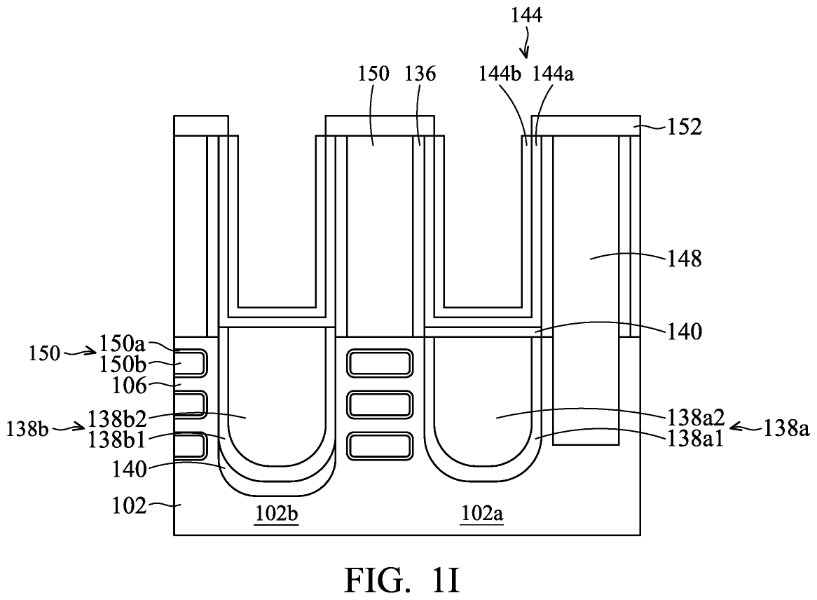

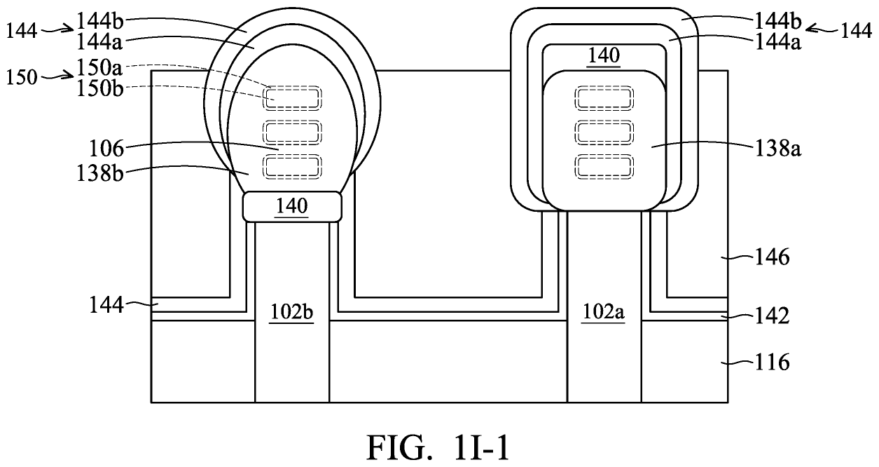

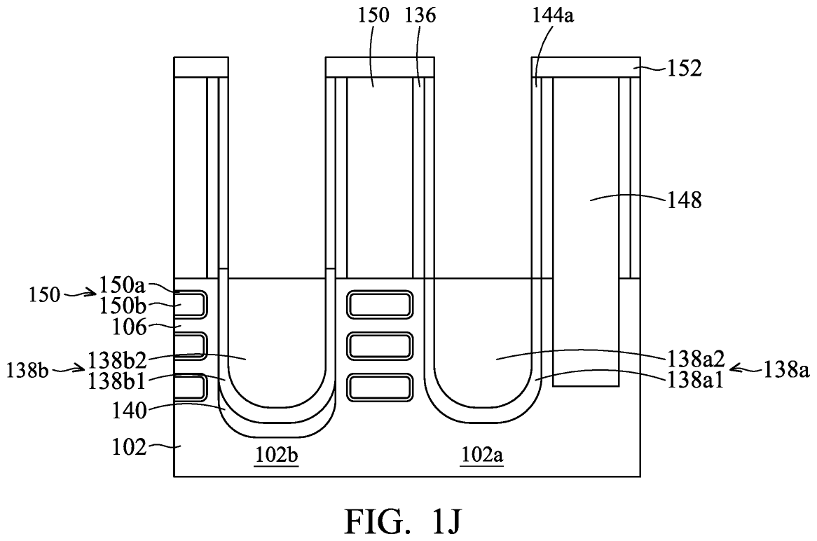

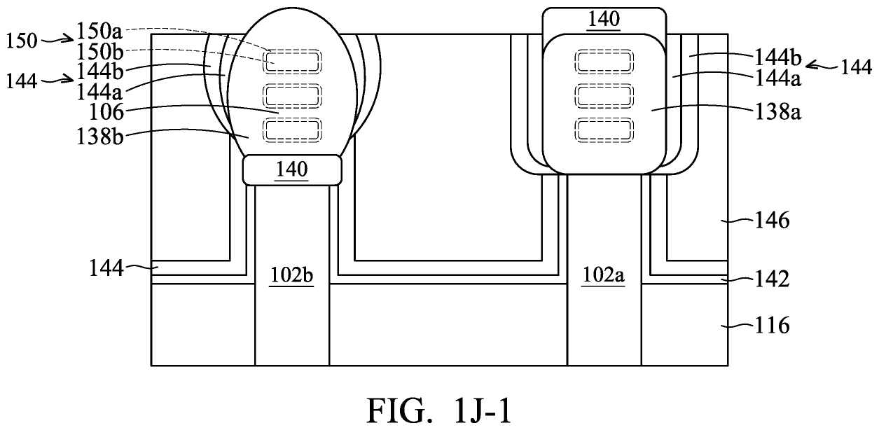

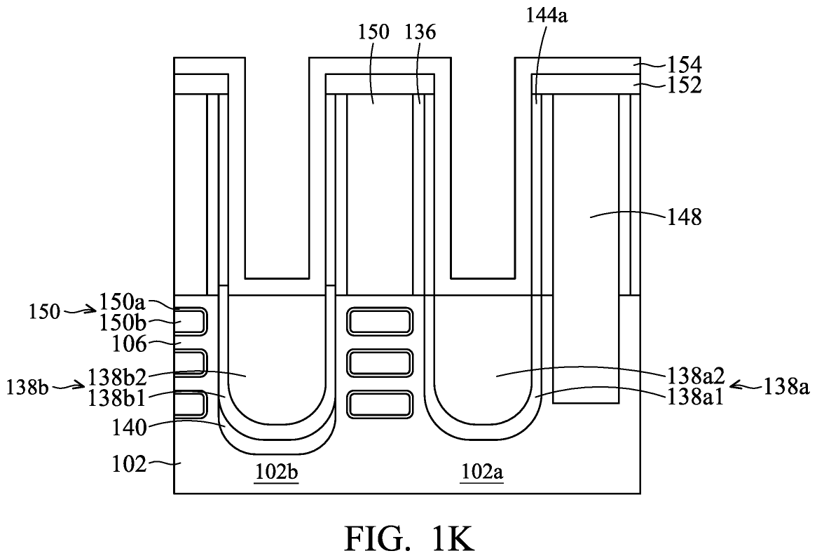

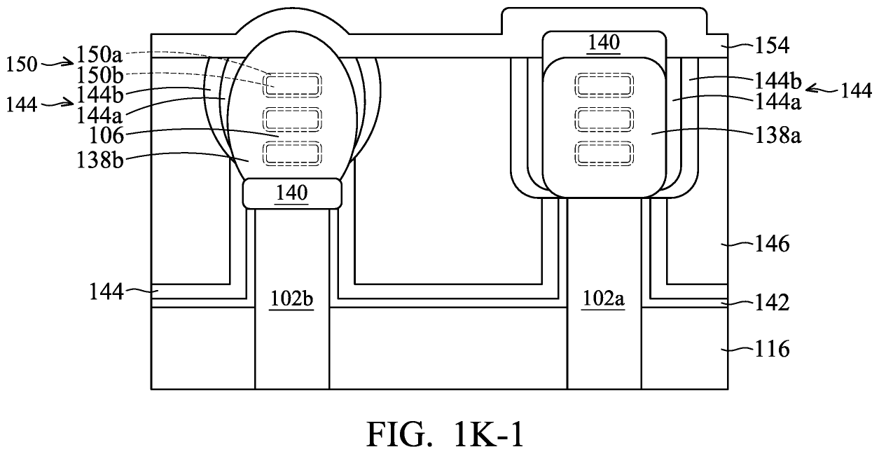

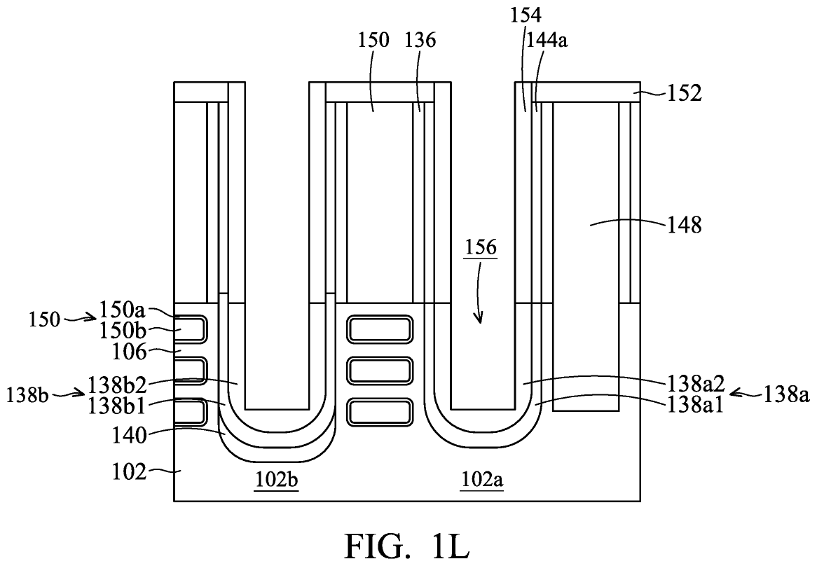

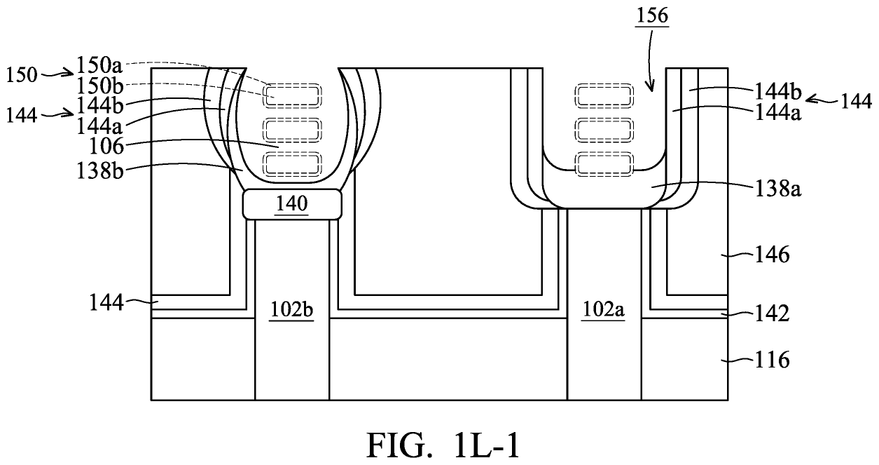

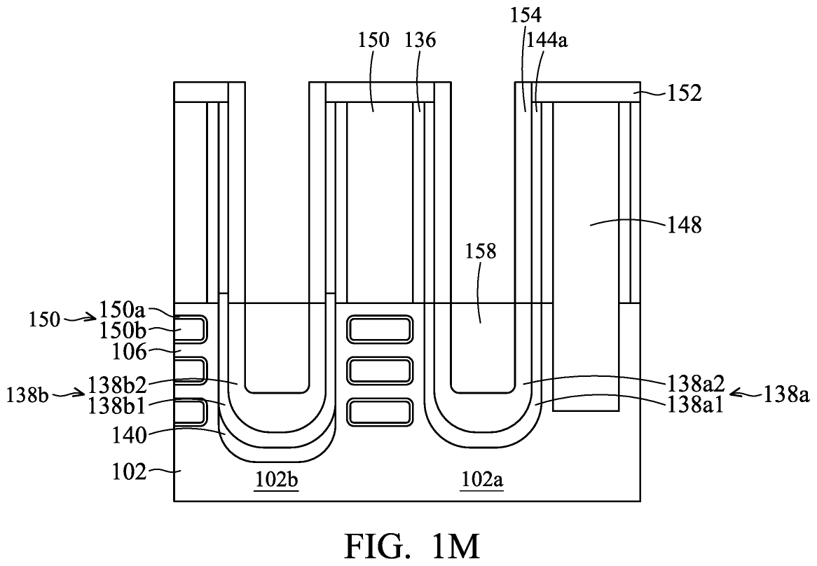

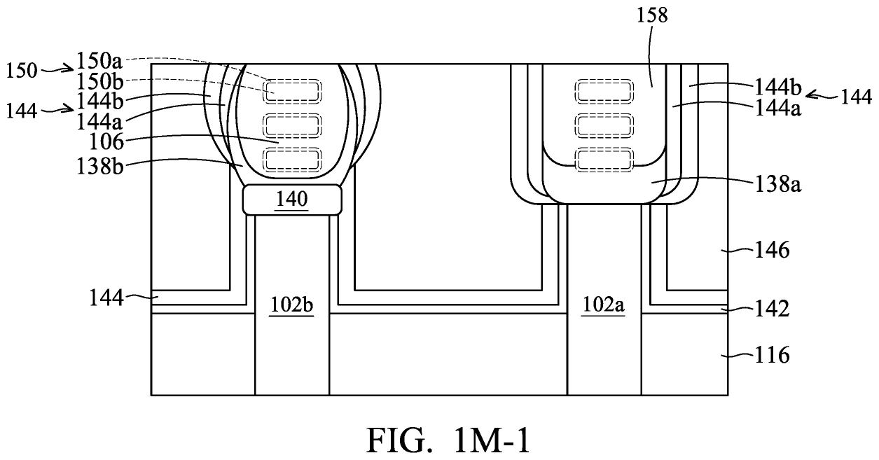

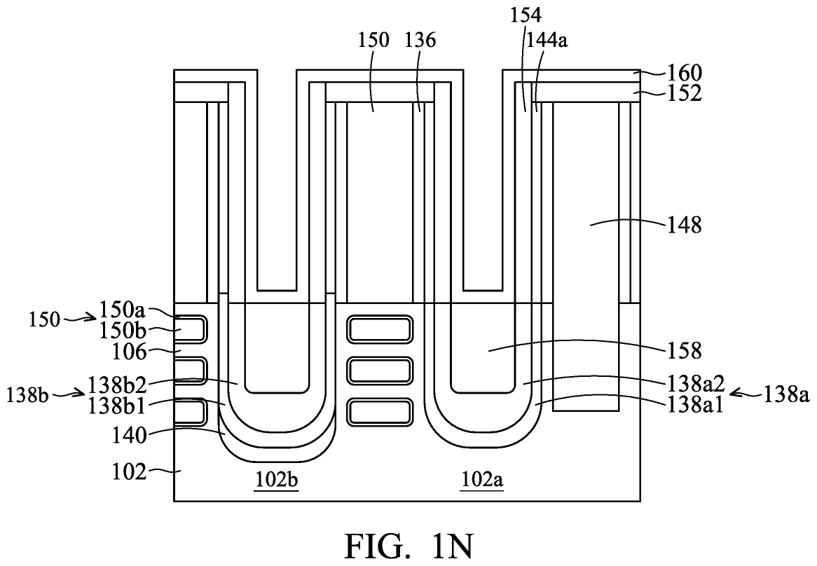

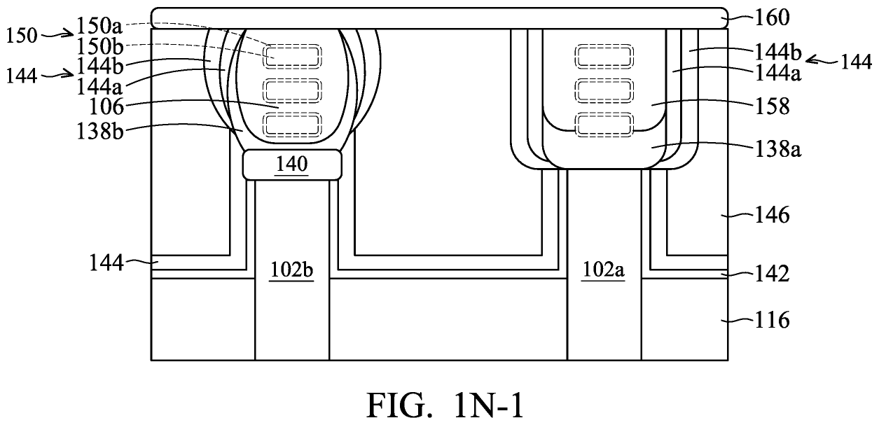

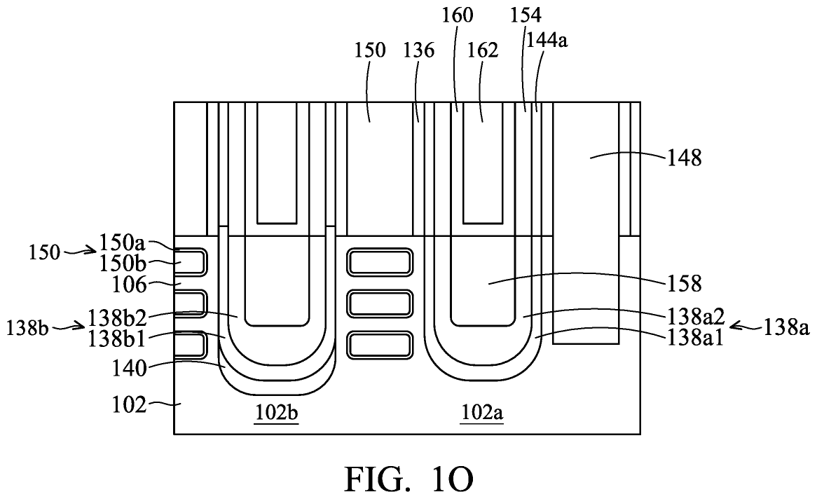

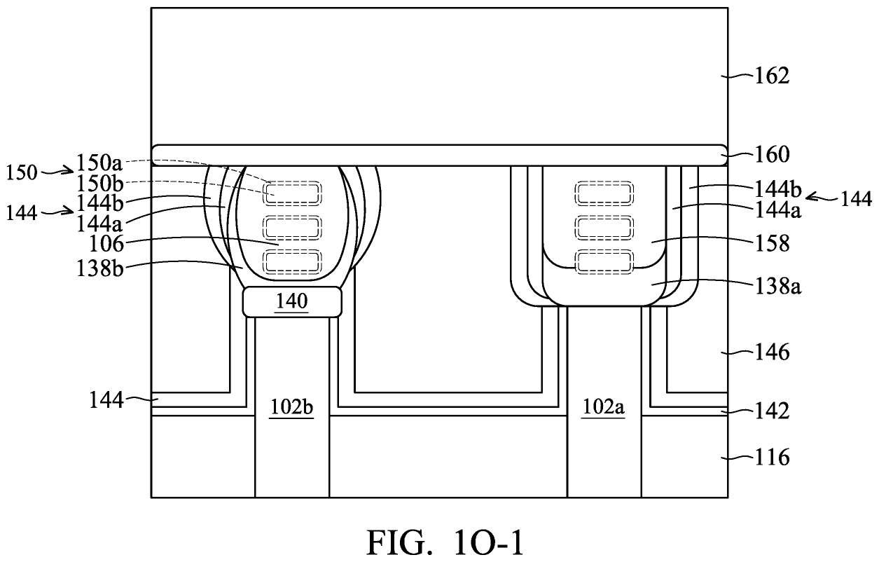

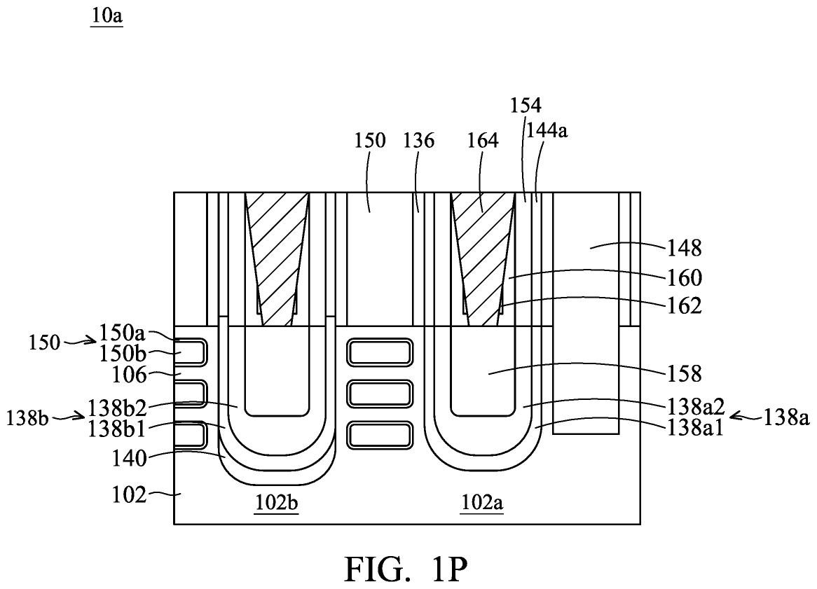

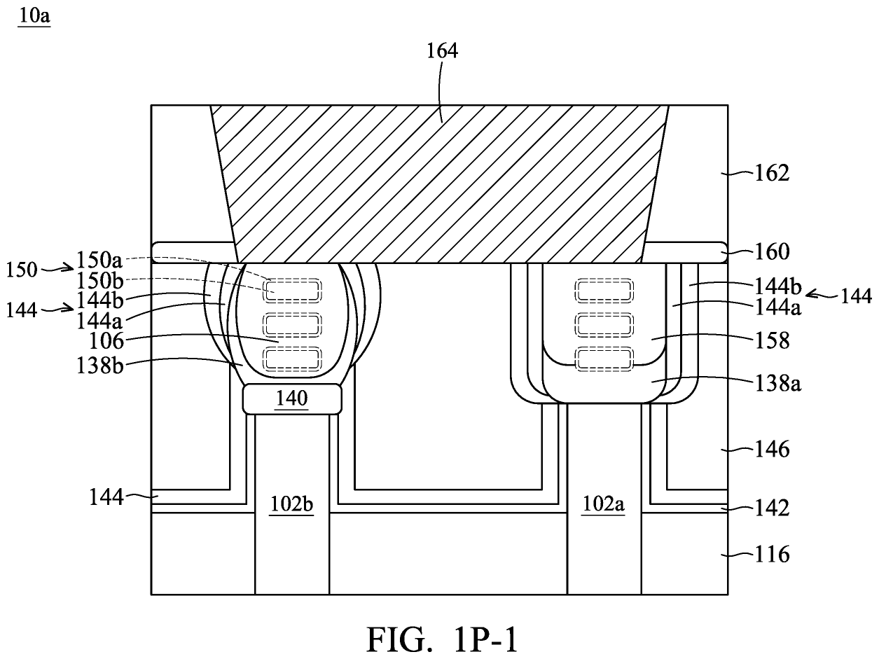

The semiconductor device structure 10a may be a nanostructure transistor. FIGS. 1A-1F are perspective representations of various stages of forming a semiconductor device structure 10a, in accordance with some embodiments of the disclosure. FIGS. 1G, 1G-1, 1H, 1H-1, 1I, 1I-1, 1J, 1J-1, 1K, 1K-1, 1L, 1L-1, 1M, 1M-1, 1N, 1N-1, 1O, 1O-1, 1P and 1P-1 are cross-sectional representations of various stages of forming a semiconductor device structure, in accordance with some embodiments of the disclosure. FIGS. 1G, 1H, 1I, 1J, 1K, 1L, 1M, 1N, 1O and 1P show cross-sectional representations taken along line 1-1 in FIG. 1F. FIGS. 1G-1, 1H-1, 1I-1, 1J-1, 1K-1, 1L-1, 1M-1, 1N-1, 1O-1 and 1P-1 show cross-sectional representations taken along line 2-2 in FIG. 1F.

A semiconductor stack 108 including first semiconductor material layers 104 and second semiconductor material layers 106 are formed over a substrate 102, as shown in FIG. 1A in accordance with some embodiments. The substrate 102 may be a semiconductor wafer such as a silicon wafer. The substrate 102 may also include other elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium nitride, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP. The substrate 102 may include an epitaxial layer. For example, the substrate 102 may be an epitaxial layer overlying a bulk semiconductor. In addition, the substrate 102 may also be semiconductor on insulator (SOI). The SOI substrate may be fabricated by a wafer bonding process, a silicon film transfer process, a separation by implantation of oxygen (SIMOX) process, other applicable methods, or a combination thereof. The substrate 102 may be an N-type substrate. The substrate 102 may be a P-type substrate.

Next, first semiconductor material layers 104 and second semiconductor material layers 106 are alternating stacked over the substrate 102 to form the semiconductor stack 108, as shown in FIG. 1A in accordance with some embodiments. The first semiconductor material layers 104 and the second semiconductor material layers 106 may include Si, Ge, SiGe, GaAs, InSb, GaP, GaSb, InAlAs, InGaAs, GaSbP, GaAsSb, or InP. The first semiconductor material layers 104 and second semiconductor material layers 106 may be made of different materials with different etching rates. In some embodiments, the first semiconductor material layers 104 are made of SiGe and the second semiconductor material layers 106 are made of Si.

The first semiconductor material layers 104 and second semiconductor material layers 106 may be formed by low pressure chemical vapor deposition (LPCVD) process, epitaxial growth process, other applicable methods, or a combination thereof. The epitaxial growth process may include molecular beam epitaxy (MBE), metal organic chemical vapor deposition (MOCVD), or vapor phase epitaxy (VPE).

It should be noted that, although there are three layers of the first semiconductor material layers 104 and three layers of the second semiconductor material layers 106 shown in FIGS. 1A, the number of the first semiconductor material layers 104 and second semiconductor material layers 106 are not limited herein, depending on the demand of performance and process. For example, the semiconductor structure may include two to five layers of the first semiconductor material layers 104 and two to five layers of the second semiconductor material layers 106.

Next, a mask structure may be formed over the semiconductor stack 108. The mask structure may be a multilayer structure including a pad layer and a hard mask layer formed over the pad layer. The pad layer may be made of silicon oxide, which may be formed by thermal oxidation or CVD. The hard mask layer may be made of silicon nitride, which may be formed by CVD, such as LPCVD or plasma-enhanced CVD (PECVD).

After the first semiconductor material layers 104 and the second semiconductor material layers 106 are formed as the semiconductor stack 108 over the substrate 102, the semiconductor stack 108 is patterned to form fin structures 112 using the mask structure as a mask layer, as shown in FIG. 1B in accordance with some embodiments. The fin structures 112 may include base fin structures and the semiconductor stack 108, including the first semiconductor material layers 104 and the second semiconductor material layers 106, formed over the base fin structure.

The patterning process may include forming a mask structure over the first semiconductor material layers 104 and the second semiconductor material layers 106 and etching the semiconductor stack 108 and the underlying substrate 102 through the mask structure.

The patterning process of forming the fin structures 112 may include a photolithography process and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

After the fin structures 112 are formed, a liner layer may be formed over the fin structures 112 and in the trenches between the fin structures 112. The liner layer may be conformally formed over the substrate 102, the fin structures 112, and the mask structure covering the fin structures 112. The liner layer may be used to protect the fin structures 112 from being damaged in the following processes (such as an anneal process or an etching process). The liner layer may be made of silicon nitride. The liner layer may be formed by using thermal oxidation, a CVD process, an atomic layer deposition (ALD) process, an LPCVD process, a plasma enhanced CVD (PECVD) process, an HDPCVD process, a flowable CVD (FCVD) process, another applicable process, or a combination thereof.

Next, an isolation material 116 is then filled into the trenches between the fin structures 112 and over the liner layer, as shown in FIG. 1C in accordance with some embodiments. The isolation material 116 may be made of silicon oxide, silicon nitride, silicon oxynitride (SiON), fluoride-doped silicate glass (FSG), other low-k dielectric materials, or a combination thereof. The isolation material 116 may be deposited by a deposition process, such as a chemical vapor deposition (CVD) process (e.g. a flowable CVD (FCVD) process), a spin-on-glass process, or another applicable process.

Next, the hard mask layer over the fin structures 112 may be removed, and the pad layer over the fin structures 112 may be exposed. The hard mask layer may be removed by performing a planarization process such as a chemical mechanical polishing (CMP) process.

Next, the isolation material 116 is etched back using an etching process, and an isolation structure 116 is formed surrounding the base fin structure, as shown in FIG. 1D in accordance with some embodiments. The etching process may be used to remove the top portion of the isolation material 116. The pad layer over the fin structure 112 may be removed in the etching process. As a result, the semiconductor stack 108 may be exposed. The isolation structure 116 may be a shallow trench isolation (STI) structure 116. The isolation structure 116 may be configured to electrically isolate active regions such as fin structures 112 of the semiconductor structure 10a and prevent electrical interference and crosstalk.

Next, a protection layer 142 may be formed over the isolation structure 116 and the substrate 102 (shown in subsequent figures). The protection layer 142 may be made of a dielectric material such as silicon oxide. The protection layer 142 may be formed by CVD, PVD, ALD, spin-on coating, or another applicable process.

Next, a dummy gate structure 124 is formed over and across the fin structures 112, as shown in FIG. 1E in accordance with some embodiments. The dummy gate structure 124 may be used to define the source/drain regions and the channel regions of the resulting semiconductor structure 10a. The dummy gate structure 124 may include a dummy gate dielectric layer 126 and a dummy gate electrode layer 128. The dummy gate dielectric layer 126 and the dummy gate electrode layer 128 may be replaced by the following steps to form a real gate structure with a high-k dielectric layer and a metal gate electrode layer.

The dummy gate dielectric layer 126 may include one or more dielectric materials, such as silicon oxide, silicon nitride, silicon oxynitride (SiON), HfO₂, HfZrO, HfSiO, HfTIO, HfAIO, or a combination thereof. The dummy gate dielectric layer 126 may be formed by an oxidation process (e.g., a dry oxidation process, or a wet oxidation process), a chemical vapor deposition process, other applicable processes, or a combination thereof. Alternatively, the dummy gate dielectric layer 126 may include a high-k dielectric layer (e.g., the dielectric constant is greater than 3.9) such as hafnium oxide (HfO₂). Alternatively, the high-k dielectric layer may include other high-k dielectrics, such as LaO, AlO, ZrO, TiO, Ta₂O₅, Y₂O₃, SrTiO₃, BaTiO₃, BaZrO, HfZrO, HfLaO, HfTaO, HfSiO, HfSiON, HfTIO, LaSiO, AlSiO, (Ba, Sr)TiO₃, Al₂O₃, other applicable high-k dielectric materials, or a combination thereof. The high-k dielectric layer may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

The dummy gate electrode layer 128 may include polycrystalline-silicon (poly-Si), poly-crystalline silicon-germanium (poly-SiGe), other applicable materials, or a combination thereof. The dummy gate electrode layer 128 may be formed by a chemical vapor deposition process (e.g., a low pressure chemical vapor deposition process, or a plasma enhanced chemical vapor deposition process), a physical vapor deposition process (e.g., a vacuum evaporation process, or a sputtering process), other applicable processes, or a combination thereof.

Next, a hard mask layer 130 is formed over the dummy gate structure 124, as shown in FIG. 1E in accordance with some embodiments. The hard mask layer 130 may include multiple layers, such as an oxide layer and a nitride layer. In some embodiments, the oxide layer includes silicon oxide, and the nitride layer includes silicon nitride.

The formation of the dummy gate structure 124 may include conformally forming a dielectric material as the dummy gate dielectric layer 126. Afterwards, a conductive material may be formed over the dielectric material as the dummy gate electrode layer 128. The hard mask layer 130, including the oxide layer and the nitride layer, may be formed over the conductive material. Next, the dielectric material and the conductive material may be patterned and etched through the hard mask layer 130 to form the dummy gate structure 124, as shown in FIG. 1E in accordance with some embodiments. The dummy gate dielectric layer 126 and the dummy gate electrode layer 128 may be etched by a dry etching process. After the etching process, the first semiconductor material layers 104 and the second semiconductor material layers 106 may be exposed at opposite sides of the dummy gate structure 124.

Next, a conformal dielectric layer is formed over the substrate 102 and the dummy gate structure 124, and then an etching process is performed. A pair of gate spacer layers 136 is formed over opposite sidewalls of the dummy gate structure 124, as shown in FIG. 1E in accordance with some embodiments

The gate spacer layers 136 may be multi-layer structures formed by different materials with different etching selectivity. The gate spacer layers 136 may be made of silicon oxide, silicon nitride, silicon oxynitride, and/or dielectric materials. The gate spacer layers 136 may be formed by a chemical vapor deposition (CVD) process, a spin-on-glass process, or another applicable process.

After the gate spacer layers 136 are formed, the first semiconductor material layers 104 and the second semiconductor material layers 106 of the fin structures 112 not covered by the dummy gate structure 124 and the gate spacer layers 136 are etched to form the source/drain opening beside the dummy gate structure 124, as shown in FIG. 1F in accordance with some embodiments. A recess may be formed in the isolation structure 116 when etching the first semiconductor material layers 104 and the second semiconductor material layers 106 of the fin structures 112. The protection layer 142 not covered by the dummy gate structure 124 and the gate spacer layers 136 may be consumed during the etching process.

The fin structures 112 may be recessed by performing a number of etching processes. That is, the first semiconductor material layers 104 and the second semiconductor material layers 106 of the fin structures 112 may be etched in different etching processes. The etching process may be a dry etching process or a wet etching process. The fin structures 112 may be etched by a dry etching process.

Next, the first semiconductor material layers 104 may be laterally etched from the source/drain opening to form recesses. The outer portions of the first semiconductor material layers 104 may be removed, and the inner portions of the first semiconductor material layers 104 under the dummy gate structure 124 and the gate spacer layers 136 may remain. After the lateral etching process, the sidewalls of the etched first semiconductor material layers 104 may be not aligned with the sidewalls of the second semiconductor material layers 106.

The lateral etching of the first semiconductor material layers 104 may be a dry etching process, a wet etching process, or a combination thereof. In some embodiments, the first semiconductor material layers 104 are Ge or SiGe and the second semiconductor material layers 106 are Si, and the first semiconductor material layers 104 are selectively etched to form the recesses by using a wet etchant such as, but not limited to, ammonium hydroxide (NH₄OH), tetramethylammonium hydroxide (TMAH), ethylenediamine pyrocatechol (EDP), or potassium hydroxide (KOH) solutions, or the like.

Next, an inner spacer may be formed in the recess. The inner spacer may provide a barrier between subsequently formed source/drain epitaxial structures and gate structure. The inner spacer may be made of a dielectric material such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. The inner spacer may be formed using a deposition process. The deposition process may include a CVD process (such as LPCVD, PECVD, SACVD, or FCVD), an ALD process, another applicable method, or a combination thereof.

Next, a first source/drain epitaxial structure 138a is formed in the source/drain opening in the first region 102a of the substrate 102, as shown in FIGS. 1G and 1G-1 in accordance with some embodiments. The first source/drain epitaxial structure 138a may be formed over opposite sides of the dummy gate structure 124. The first source/drain epitaxial structure 138a may refer to a source or a drain, individually or collectively dependent upon the context.

A strained material may be grown in the source/drain opening using an epitaxial (epi) process to form the first source/drain epitaxial structure 138a. In addition, the lattice constant of the strained material may be different from the lattice constant of the substrate 102. The first source/drain epitaxial structure 138a may include SiGeB, SiGe, other applicable materials, or a combination thereof. The first source/drain epitaxial structure 138a may be formed by an epitaxial growth step, such as metalorganic chemical vapor deposition (MOCVD), metalorganic vapor phase epitaxy (MOVPE), plasma-enhanced chemical vapor deposition (PECVD), remote plasma-enhanced chemical vapor deposition (RP-CVD), molecular beam epitaxy (MBE), hydride vapor phase epitaxy (HVPE), liquid phase epitaxy (LPE), chloride vapor phase epitaxy (CI-VPE), or any other suitable method.

The first source/drain epitaxial structure 138a may be in-situ doped during the epitaxial growth process. For example, the first source/drain epitaxial structure 138a may be the epitaxially grown SiGe doped with boron (B). The first source/drain epitaxial structure 138a may be doped in one or more implantation processes after the epitaxial growth process.

The first source/drain epitaxial structure 138a may include a first portion 138a1 formed at the bottom of the source/drain opening, and a second portion 138a2 filled over the first portion 138al in the source/drain opening, as shown in FIG. 1G in accordance with some embodiments. The first portion 138al may be made of dielectric material such as silicon nitride, silicon oxide, silicon oxynitride (SiON), other applicable materials, or a combination thereof. The first portion 138al also may be made of un-doped or lower doped Si or SiGe. The second portion 138a2 may be doped SiGe. In some embodiments, the dopant concentration of the second portion 138a2 is higher than the dopant concentration of the first portion 138al. Therefore, dopant out-diffusing issue may be prevented.

Next, an isolation layer 140 is formed over the first source/drain epitaxial structure 138a and in the source/drain opening in the second region 102b of the substrate 102, as shown in FIGS. 1G and 1G-1 in accordance with some embodiments. The isolation layer 140 may provide isolation between the substrate 102 and the subsequently formed source/drain epitaxial structure. The isolation layer 140 may be made of a dielectric material such as silicon nitride, silicon oxide, silicon oxynitride (SiON), other applicable materials, or a combination thereof. The isolation layer 140 may be formed by CVD, PVD, ALD, spin-on coating, or another applicable process.

Next, a second source/drain epitaxial structure 138b is formed in the source/drain opening in the second region 102b of the substrate 102, as shown in FIGS. 1G and 1G-1 in accordance with some embodiments. The second source/drain epitaxial structure 138b may refer to a source or a drain, individually or collectively dependent upon the context.

The second source/drain epitaxial structure 138b may include SiP, SiAs, other applicable materials, or a combination thereof. The processes for forming the second source/drain epitaxial structure 138b may be the same as, or similar to, those used to form the first source/drain epitaxial structure 138a. For the purpose of brevity, the descriptions of these processes are not repeated herein.

The second source/drain epitaxial structure 138b may be the epitaxially grown Si doped with carbon to form silicon: carbon (Si: C) source/drain features, phosphorous to form silicon: phosphor (Si: P) source/drain features, or both carbon and phosphorous to form silicon carbon phosphor (SiCP) source/drain features.

The second source/drain epitaxial structure 138b may include a first portion 138b1 formed at the bottom of the source/drain opening, and a second portion 138b2 filled over the first portion 138b1 in the source/drain opening, as shown in FIG. 1G in accordance with some embodiments. The first portion 138b1 may be made of dielectric material such as silicon nitride, silicon oxide, silicon oxynitride (SiON), other applicable materials, or a combination thereof. The first portion 138b1 also may be made of un-doped or lower doped Si or SiP. The second portion 138b2 may be doped SiP. In some embodiments, the dopant concentration of the second portion 138b2 is higher than the dopant concentration of the first portion 138b1. Therefore, dopant out-diffusing issue may be prevented.

Next, a first etch stop layer 144 may be formed over the first source/drain epitaxial structure 138a and the second source/drain epitaxial structure 138b, as shown in FIGS. 1G and 1G-1 in accordance with some embodiments. More specifically, the first etch stop layer 144 may cover the sidewalls of the gate spacer layers 136, the top surface of the first source/drain epitaxial structure 138a, and the top surface of the second source/drain epitaxial structure 138b. The first etch stop layer 144 may be made of a dielectric material such as silicon nitride, silicon oxide, silicon oxynitride (SiON), other applicable materials, or a combination thereof. The first etch stop layer 144 may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

The first etch stop layer 144 may be a bi-layer structure including a first dielectric layer 144a and a second dielectric layer 144b, as shown in FIG. 1G in accordance with some embodiments. The first dielectric layer 144a may be conformally formed over the sidewalls of the gate spacer layers 136, the top surface of the first source/drain epitaxial structure 138a, and the top surface of the second source/drain epitaxial structure 138b. The second dielectric layer 144b may be conformally formed over the first dielectric layer 144a. The first dielectric layer 144a may be made of silicon oxynitride (SiON), and the second dielectric layer 144b may be made of silicon nitride. With a bi-layer first etch stop layer 144, the capacitance may be reduced.

After the first etch stop layer 144 is formed, a first inter-layer dielectric (ILD) structure 146 is formed over the first etch stop layer 144, the first source/drain epitaxial structure 138a and the second source/drain epitaxial structure 138b, as shown in FIGS. 1G and 1G-1 in accordance with some embodiments. In some embodiments, the first ILD structure 146 surrounds the first source/drain epitaxial structure 138a and the second source/drain epitaxial structure 138b.

The first ILD structure 146 may include multilayers made of multiple dielectric materials, such as silicon oxide (SiOₓ, where x may be a positive integer), silicon oxycarbide (SiCO_{y}, where y may be a positive integer), silicon oxycarbonitride (SiNCO_{z}, where z may be a positive integer), silicon nitride, silicon oxynitride, phosphosilicate glass (PSG), borophosphosilicate glass (BPSG), low-k dielectric material, or another applicable dielectric material. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The first ILD structure 146 may be formed by chemical vapor deposition (CVD), physical vapor deposition (PVD), atomic layer deposition (ALD), spin-on coating, or another applicable process.

Afterwards, a planarizing process or an etch-back process may be performed on the first ILD structure 146 until the top surface of the dummy gate structure 124 is exposed. After the planarizing process, the top surface of the dummy gate structure 124 may be substantially level with the top surfaces of the gate spacer layers 136 and the first ILD structure 146. The planarizing process may include a grinding process, a chemical mechanical polishing (CMP) process, an etching process, other applicable processes, or a combination thereof.

Next, a portion of the dummy gate structures 124 is removed, and an opening may be formed. Later, a dielectric structure 148 is formed in the opening, as shown in FIG. 1G in accordance with some embodiments.

A portion of the dummy gate structure 124 may be removed by patterning process such as a photolithography and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

The dielectric structure 148 may be made of a single or a multi-layer material including oxides, nitrides, SiO₂, SiCO, SiO2: F, SiN, SiCN, nitrogen, and carbon base content materials. The dielectric structure 148 may be formed by CVD, PVD, ALD, spin-on coating, or another applicable process.

Next, the remain dummy gate structure 124 may be removed, and a trench may be formed between the gate spacer layers 136 over the fin structures 112 and the second semiconductor material layers 106 are exposed from the trench.

The dummy gate structure 124 may be removed by a dry etching process or a wet etching process. The removal process may include one or more etching processes. For example, when the dummy gate electrode layer 128 are polysilicon, a wet etchant such as a tetramethylammonium hydroxide (TMAH) solution may be used to selectively remove the dummy gate electrode layer 128. Afterwards, the dummy gate dielectric layer 126 may be removed using a plasma dry etching, a dry chemical etching, and/or a wet etching.

Next, the first semiconductor material layers 104 may be removed and gaps may be formed between the second semiconductor material layers 106. More specifically, the second semiconductor material layers 106 exposed by the gaps form nanostructures 106, and the nanostructures 106 are configured to function as channel regions 106 in the resulting semiconductor devices 10a in accordance with some embodiments.

The first semiconductor material layers 104 may be removed by performing one or more etching processes. The etching process may include a selective wet etching process, such as APM (e.g., ammonia hydroxide-hydrogen peroxide-water mixture) etching process. The wet etching process uses etchants such as ammonium hydroxide (NH₄OH), TMAH, ethylenediamine pyrocatechol (EDP), and/or potassium hydroxide (KOH) solutions.

Next, gate structures 150 are formed surrounding the nanostructures 106 and over the nanostructures 106, as shown in FIGS. 1G and 1G-1 in accordance with some embodiments. Gate structures 150 are formed surrounding the nanostructures 106 to form gate-all-around (GAA) transistor structures. Therefore, the gate control ability may be enhanced.

It should be noted that, the gate structure 150 is invisible in FIG. 1G-1. The gate structure 150 is shown in dashed line to indicate the position of the gate structure 150.

In some embodiments as shown in FIGS. 1G and 1G-1, the gate structures 150 are multi-layered structures. Each of the gate structures 150 may include an interfacial layer, a gate dielectric layer 150a, a work function layer 150b, and a gate electrode layer.

The interfacial layer may be formed around the nanostructures 106 and on the exposed portions of the base fin structures. The interfacial layer may be made of silicon oxide, and the interfacial layer may be formed by thermal oxidation.

The gate dielectric layer 150a may be formed over the interfacial layer, so that the nanostructures 106 are surrounded (e.g. wrapped) by the gate dielectric layer 150a. In addition, the gate dielectric layer 150a also covers the sidewalls of the gate spacer layers 136 and the inner spacers in accordance with some embodiments. The gate dielectric layer 150a may be made of one or more layers of dielectric materials, such as HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other applicable high-k dielectric materials, or a combination thereof. The gate dielectric layer 150a may be formed using CVD, ALD, other applicable methods, or a combination thereof.

Next, the work function layer 150b is conformally formed over the gate dielectric layer 150a, as shown in FIGS. 1G and 1G-1 in accordance with some embodiments. The work function layer 150b may be made of a metal material. The metal material of the work function layer 150b formed in the second region 102b in the substrate 102 may include an N-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), or a combination thereof. The work function layer 150b may be formed by using CVD, ALD, other applicable methods, or a combination thereof.

The metal material of the work function layer 150b formed in the first region 102a in the substrate 102 may include a P-work-function metal. The P-work-function metal may include titanium nitride (TiN), tungsten nitride (WN), tantalum nitride (TaN), ruthenium (Ru) or a combination thereof. The work function layer 150b may be formed by using CVD, ALD, other applicable methods, or a combination thereof.

Next, a gate electrode layer may be formed over the work function layer 150b. The gate electrode layer may be made of one or more layers of conductive material, such as aluminum, copper, titanium, tantalum, tungsten, cobalt, molybdenum, tantalum nitride, nickel silicide, cobalt silicide, TIN, WN, TiAl, TiAlN, TaCN, TaC, TaSiN, metal alloys, another suitable material, or a combination thereof. The gate electrode layer may be formed using CVD, ALD, electroplating, another applicable method, or a combination thereof. After the gate electrode layer is formed, a planarization process such as CMP or an etch-back process may be performed.

Next, a hard mask layer 152 is selectively formed over the gate structure 150 and the first dielectric layer 144a of the first etch stop layer 144, as shown in FIG. 1H in accordance with some embodiments. In some embodiments, the hard mask layer 152 is made of metal. In some embodiments, the hard mask layer 152 is made of Ti. The first ILD structure 146 and the second dielectric layer 144b of the first etch stop layer 144 may be exposed from the hard mask layer 152. The hard mask layer 152 may be formed using CVD, ALD, electroplating, another applicable method, or a combination thereof.

Afterwards, the first ILD structure 146 is recessed, and the second dielectric layer 144b of the first etch stop layer 144 is exposed, as shown in FIGS. 11 and 1I-1 in accordance with some embodiments. In some embodiments, the top surface of the remaining first ILD structure 146 is higher than or substantially level with the top surface of the topmost nanostructure 106. The first ILD structure 146 may be recessed by a dry etching process or a wet etching process.

Next, the first dielectric layer 144a and the second dielectric layer 144b of the first etch stop layer 144 and the isolation layer 140 are etched, and the first source/drain epitaxial structure 138a and the second source/drain epitaxial structure 138b are exposed, as shown in FIGS. 1J and 1J-1 in accordance with some embodiments. The first etch stop layer 144 and the isolation layer 140 may be etched by a dry etching process or a wet etching process. In some embodiments, the first etch stop layer 144 and the isolation layer 140 is etched by a dry etching process. In some embodiments, the second dielectric layer 144b of the first etch stop layer 144 is removed when etching back the first etch stop layer 144.

The second portion 138b2 of the second source/drain epitaxial structure 138b may be etched while etching back the first etch stop layer 144. In some embodiments, the top surface of the first portion 138b1 of the second source/drain epitaxial structure 138b is higher than the top surface of the second portion 138b2 of the second source/drain epitaxial structure 138b after the etching process. In some embodiments, the top surface of the second portion 138b2 of the second source/drain epitaxial structure 138b is substantially level with the top surface of the first source/drain epitaxial structure 138a after the etching process.

Next, dopants may be implanted in the first source/drain epitaxial structure 138a and the second source/drain epitaxial structure 138b, and an anneal process may be performed to activate the dopants. In some embodiments, the dopants are implanted over the top surface of the first source/drain epitaxial structure 138a and the second source/drain epitaxial structure 138b. The dopants implanted in the first region 102a of the substrate 102 may be P-type dopant such as B, Ga, Al, In, BF3⁺ ions, or a combination thereof. The dopants implanted in the second region 102b of the substrate 102 may be N-type dopant may such as P, As, N, Sb ions, or a combination thereof. The anneal process may include a dynamic surface annealing (DSA) process, a rapid thermal annealing (RTA) process, laser anneal, furnace anneal, flash lamp anneal, other suitable annealing process, or a combination thereof.

The implantation process may also be performed in subsequent process, which will be described later.

Later, a spacer layer 154 is conformally formed over the gate structure 150, the first source/drain epitaxial structure 138a, the second source/drain epitaxial structure 138b, the first dielectric layer 144 of the first etch stop layer 144, and the remaining first ILD structure 146, as shown in FIGS. 1K and 1K-1 in accordance with some embodiments. In some embodiments, the spacer layer 154 is formed over the sidewalls of the first etch stop layer 144. The spacer layer 154 may be a dielectric layer made of SiCON, SiO₂, SiCO, oxide, carbon base content materials, other suitable materials, or a combination thereof. The spacer layer 154 may be formed using CVD, ALD, electroplating, another applicable method, or a combination thereof.

Next, the spacer layer 154, the first source/drain epitaxial structure 138a and the second source/drain epitaxial structure 138b are etched, and a recess 156 is formed in the first source/drain epitaxial structure 138a and the second source/drain epitaxial structure 138b, as shown in FIGS. 1L and 1L-1 in accordance with some embodiments. The spacer layer 154, the first source/drain epitaxial structure 138a and the second source/drain epitaxial structure 138b may be etched by a dry etching process or a wet etching process. In some embodiments, the spacer layer 154, the first source/drain epitaxial structure 138a and the second source/drain epitaxial structure 138b is etched by a dry etching process.

In some embodiments, the top surface of the bottommost nanostructure 106 is higher than the bottom surface of the recess 156. It should be noted that, although the bottom surface of the bottommost nanostructure 106 in the second region 102b of the substrate 102 is higher than the bottom surface of the recess 156, and the bottom surface of the bottommost nanostructure 106 in the first region 102a of the substrate 102 is lower than the bottom surface of the recess 156, the recess 156 shown in FIGS. 1L and 1L-1 are merely an example, and is not limited therein. The etching process of forming the recess 156 may be modified, depending on the process and design needs.

Next, a silicide structure 158 is formed in the recess 156 in the first source/drain epitaxial structure 138a and the second source/drain epitaxial structure 138b, as shown in FIGS. 1M and 1M-1 in accordance with some embodiments. The silicide structure 158 may reduce the contact resistance between the first source/drain epitaxial structure 138a and the second source/drain epitaxial structure 138b and the subsequently formed contact structure over the first source/drain epitaxial structure 138a and the second source/drain epitaxial structure 138b.

The silicide structure 158 may be made of TiSi, Ti₅Si₄, TiSi₂, NiSi, NiSi₂, CoSi, CoSi₂, WSi₂ and MoSi₂, or other suitable low-resistance materials. The silicide structure 158 may be formed over the first source/drain epitaxial structure 138a and the second source/drain epitaxial structure 138b by forming a metal layer over the first source/drain epitaxial structure 138a and the second source/drain epitaxial structure 138b first. The metal layer may react with the first source/drain epitaxial structure 138a and the second source/drain epitaxial structure 138b in an annealing process and a silicide layer may be produced. Afterwards, the unreacted metal layer may be removed in an etching process and the silicide structure 158 may be formed in the recess 156.

In some embodiments, the bottom surface of the silicide structure 158 is lower than the top surface of the bottommost nanostructure 106. In some embodiments, the top surface of the silicide structure 158 is substantially level with the top surface of the substrate 102.

After forming the silicide structure 158, a second etch stop layer 160 is conformally formed over the gate structure 150, the spacer layer 152, the first ILD structure 146, and the silicide structure 158, as shown in FIGS. 1N and 1N-1 in accordance with some embodiments. The second etch stop layer 160 may be made of a dielectric material such as silicon nitride, silicon oxide, silicon oxynitride (SiON), other applicable materials, or a combination thereof. In some embodiments, the second etch stop layer 160 is made of silicon nitride. In some embodiments, the second etch stop layer 160 and the second dielectric layer 144b of the first etch sop layer 144 are made of the same material. The second etch stop layer 160 may be formed by a CVD process, an ALD process, a PVD process, other applicable processes, or a combination thereof.

Next, a second ILD structure 162 is formed over the second etch stop layer 160, and a planarization process is performed, as shown in FIGS. 1O and 1O-1 in accordance with some embodiments. The processes and materials for forming the second ILD structure 162 may be the same as, or similar to, those used to form the first ILD structure 146. For the purpose of brevity, the descriptions of these processes are not repeated herein.

Next, a gate isolation structure may be formed between the fin structures 112. The gate structure 150 may be cut by the gate isolation structure. The gate isolation structure may provide isolation between the fin structures 112. The gate isolation structure may be made of SiN, SiCN, SiCON, other suitable materials, or a combination thereof. The position of the gate isolation structure may be defined by a patterning process, and the gate isolation structure may be formed by CVD, such as LPCVD or plasma-enhanced CVD (PECVD).

Next, an opening may be formed in the second ILD structure 162. A barrier layer may be conformally formed over the bottom surface and the sidewalls of the opening. The barrier layer may be formed before filling the conductive material in the opening to prevent the conductive material from diffusing out. The barrier layer may also serve as an adhesive or glue layer. The material of the barrier layer may be TiN, Ti, other applicable materials, or a combination thereof. The barrier layer may be formed by depositing the barrier layer materials by a physical vapor deposition process (PVD) (e.g., evaporation or sputtering), an atomic layer deposition process (ALD), an electroplating process, other applicable processes, or a combination thereof.

Afterwards, a contact structure 164 is formed into the opening over the first source/drain epitaxial structure 138a and the second source/drain epitaxial structure 138b, as shown in FIGS. 1P and 1P-1 in accordance with some embodiments. In some embodiments, the silicide structure 158 is wider than the bottom surface of the contact structure 164.

The contact structure 164 may be made of a metal material (e.g., Co, Ni, W, Ti, Ta, Cu, Al, Ru, Mo, TiN, TaN, and/or a combination thereof), metal alloys, poly-Si, other applicable conductive materials, or a combination thereof. The contact structure 164 may be formed by a CVD process, a PVD process, an ALD, an electroplating process, another suitable process, or a combination thereof to deposit the conductive materials of the contact structure 164, and then a planarization process such as a chemical mechanical polishing (CMP) process or an etch back process is optionally performed to remove excess conductive materials. After the planarization process, the top surface of the contact structure 164 may be level with the top surface of the gate spacer layers 136.

By forming a deep silicide structure 158 in the first source/drain epitaxial structure 138a and the second source/drain epitaxial structure 138b, the bottommost nanostructure 106 may be enabled. The larger silicide area may reduce the resistance. The first source/drain epitaxial structure 138a and the second source/drain epitaxial structure 138b may be smaller, and the first source/drain epitaxial structure 138a and the second source/drain epitaxial structure 138b may not be merged and the height of the first source/drain epitaxial structure 138a and the second source/drain epitaxial structure 138b may be controlled. In addition, since there is no cleaning process before forming the contact structure 164, the leakage between the contact structure 164 and the gate structure 150 may be prevented. The contact structure 164 size may be smaller, and the resistance and the capacitance may be lowered. In addition, the silicide structure 158 and the gate structure 150 may not be short-circuited.

With a deep silicide structure 158 formed between forming the gate structure 150 and the gate isolation structure, the resistance may be lowered. The leakage current between the silicide structure 158 and the gate structure 150 may be prevented. The leakage current between the contact structure 164 and the gate structure 150 may also be prevented. The contact structure 164 may be smaller, and the resistance may not be increased.

Many variations and/or modifications may be made to the embodiments of the disclosure. FIG. 2 is a cross-sectional representation of a semiconductor device structure 10b. Some processes or devices are the same as, or similar to, those described in the embodiments above, and therefore the descriptions of these processes and devices are not repeated herein. The difference from the embodiments described above is that, as shown in FIG. 2 in accordance with some embodiments, the lower portion 158b of the silicide structure 158 is narrower than the upper portion 158a of the silicide structure 158.

In some embodiments, the second source/drain epitaxial structure 138b is consumed when etching back the isolation layer 140 formed over the first source/drain epitaxial structure 138a. Afterwards, the first source/drain epitaxial structure 138a and the second source/drain epitaxial structure 138b are further etched after depositing the spacer layer 154. The recess 156 may be formed by separate etching processes. Later, the silicide structure 158 with different widths is formed in the recess 156.

It should be noted that, although the silicide structure 158 with different widths is formed in the second source/drain epitaxial structure 138b in the second region 102b of the substrate 102, not limited therein. The silicide structure 158 with different widths may also be formed in the first source/drain epitaxial structure 138b in the first region 102a of the substrate 102.

With a deep silicide structure 158 formed between forming the gate structure 150 and the gate isolation structure, the resistance may be lowered. The leakage current between the silicide structure 158 and the gate structure 150 may be prevented. The leakage current between the contact structure 164 and the gate structure 150 may also be prevented. The contact structure 164 may be smaller, and the resistance may not be increased. The silicide structure 158 may have a lower portion 158b narrower than the upper portion 158a.

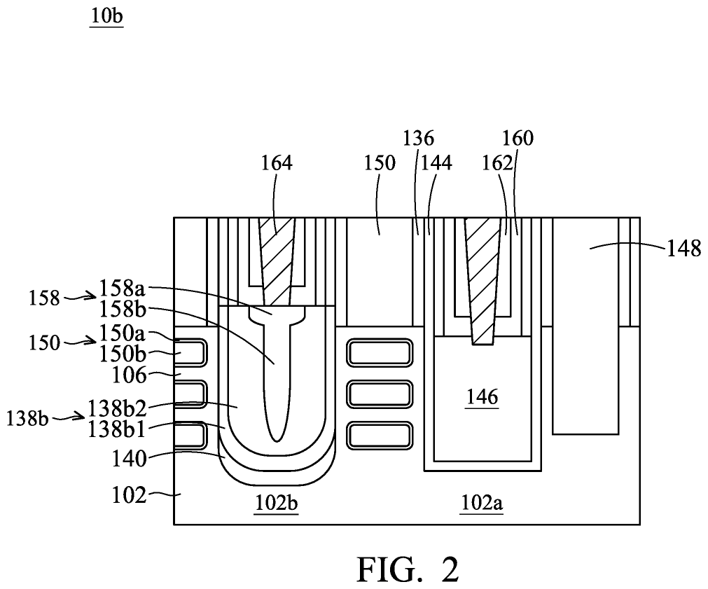

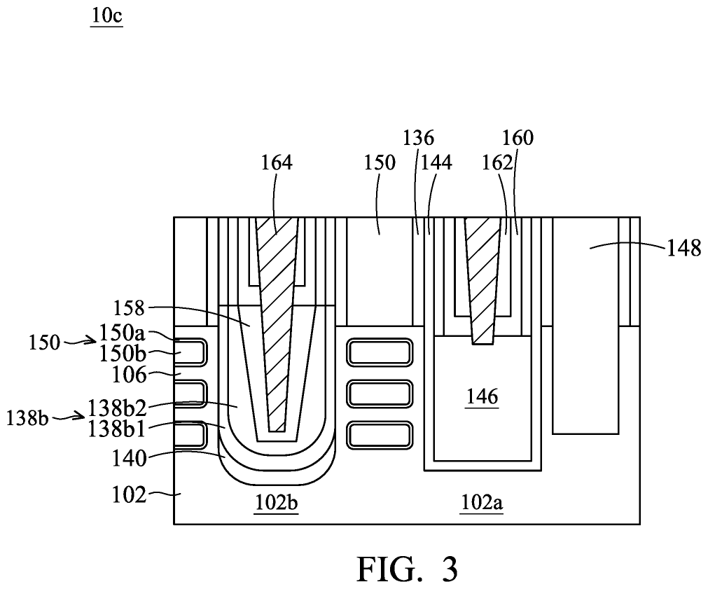

Many variations and/or modifications may be made to the embodiments of the disclosure. FIG. 3 is a cross-sectional representation of a semiconductor device structure 10c. Some processes or devices are the same as, or similar to, those described in the embodiments above, and therefore the descriptions of these processes and devices are not repeated herein. The difference from the embodiments described above is that, as shown in FIG. 3 in accordance with some embodiments, the contact structure 164 protrudes into the first source/drain epitaxial structure 138a and the second source/drain epitaxial structure 138b.

In some embodiments, the contact structure 164 protrudes in the silicide structure 158. The profile of the recess 156 may be controlled by the etching process after depositing the spacer layer 154. The recess 156 may have a tapered sidewall.

In some embodiments, the implantation process may be performed after forming the recess 156. In some embodiments, the dopants are implanted over the sidewalls of the first source/drain epitaxial structure 138a and the second source/drain epitaxial structure 138b. With tapered sidewall, the dopants may be implanted more effectively. In some embodiments, the silicide structure 158 has a tapered sidewall.

If the recess 156 is wide, the silicide structure 158 may be formed over the sidewall of the recess 156, and the contact structure 164 may be filled in the recess 156 formed in the first source/drain epitaxial structure 138a and the second source/drain epitaxial structure 138b.

With a deep silicide structure 158 formed between forming the gate structure 150 and the gate isolation structure, the resistance may be lowered. The leakage current between the silicide structure 158 and the gate structure 150 may be prevented. The leakage current between the contact structure 164 and the gate structure 150 may also be prevented. The contact structure 164 may be smaller, and the resistance may not be increased. The silicide structure 158 may have tapered sidewalls, and the contact structure 164 may protrude into the first source/drain epitaxial structure 138a and the second source/drain epitaxial structure 138b.

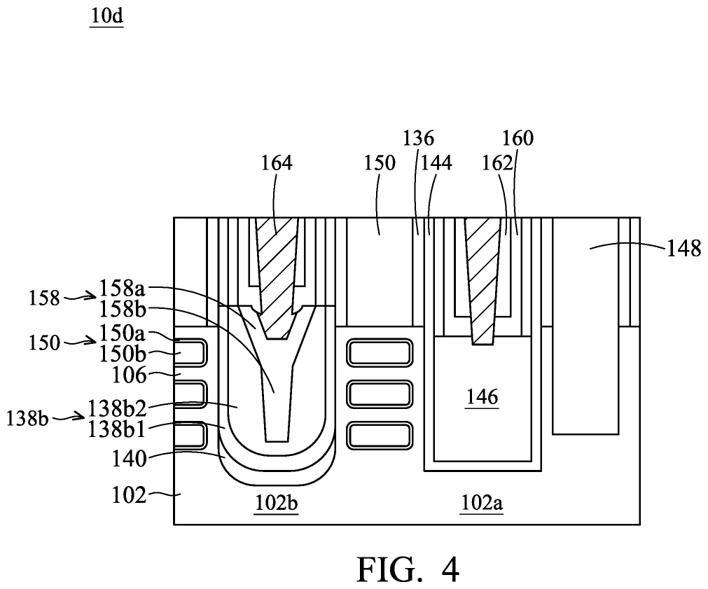

Many variations and/or modifications may be made to the embodiments of the disclosure. FIG. 4 is a cross-sectional representation of a semiconductor device structure 10d. Some processes or devices are the same as, or similar to, those described in the embodiments above, and therefore the descriptions of these processes and devices are not repeated herein. The difference from the embodiments described above is that, as shown in FIG. 4 in accordance with some embodiments, both of the upper portion 158a and the lower portion 158b of the silicide structure 158 have tapered sidewalls.

With tapered sidewalls, the dopants implanted after forming the recess 156 may be implanted more effectively. In some embodiments, the sidewall of the upper portion 158a of the silicide structure 158 is more tapered than the sidewall of the lower portion 158b of the silicide structure 158. The silicide structure 158 may be merged in the lower portion 158b of the silicide structure 158, and the contact structure 164 is formed in the upper portion 158a or the silicide structure 158. There is no need to form an extra barrier layer and to perform an extra cleaning process. The profiles of the silicide structure 158 and contact structure 164 are more easily controlled.

With a deep silicide structure 158 formed between forming the gate structure 150 and the gate isolation structure, the resistance may be lowered. The leakage current between the silicide structure 158 and the gate structure 150 may be prevented. The leakage current between the contact structure 164 and the gate structure 150 may also be prevented. The contact structure 164 may be smaller, and the resistance may not be increased. The upper portion 158a and the lower portion 158b of the silicide structure 158 may have tapered sidewalls with different slopes, and the contact structure 164 may protrude into the upper portion 158a of the silicide structure 158.

As described previously, a deep silicide structure 158 is formed in the first source/drain epitaxial structure 138a and the second source/drain epitaxial structure 138b. Larger silicide structure 158 may reduce the resistance, and deeper silicide structure 158 may enhance device performance. The deep silicide structure 158 may be formed after forming the gate structure 150 and before forming the gate isolation structure. The deep silicide structure 158 is formed with more process flexibility, the leakage and the short-circuit issue may be prevented. In some embodiments as shown in FIG. 2, the silicide structure 158 includes an upper portion 158a and a lower portion 158b with different widths. In some embodiments as shown in FIG. 3, the silicide structure 158 has a tapered sidewall and the contact structure 164 protrudes into the silicide structure 158. In some embodiments as shown in FIG. 4, the silicide structure 158 includes an upper portion 158a and a lower portion 158b with different sidewall slopes. The contact structure 164 protrudes into the upper portion 158a of the silicide structure 158.

Embodiments of a semiconductor device structure and a method for forming the same are provided. A deep silicide structure formed in the source/drain epitaxial structure may enable bottom nanostructure and enhance device performance. Forming the deep silicide structure with more flexibility may also prevent leakage or short-circuit.

In some embodiments, a method for forming a semiconductor device structure is provided. The method for forming a semiconductor device structure includes forming nanostructures over a substrate. The method for forming a semiconductor device structure also includes forming a gate structure wrapped around the nanostructures. The method for forming a semiconductor device structure also includes forming source/drain epitaxial structures over opposite sides of the nanostructures. The method for forming a semiconductor device structure also includes forming a first interlayer dielectric structure over the source/drain epitaxial structures. The method for forming a semiconductor device structure also includes removing the first interlayer dielectric structure. The method for forming a semiconductor device structure also includes forming a recess in the source/drain epitaxial structures. The method for forming a semiconductor device structure also includes forming a silicide structure in the recess. The method for forming a semiconductor device structure also includes forming a second interlayer dielectric structure over the silicide structure.

In some embodiments, a method for forming a semiconductor device structure is provided. The method for forming a semiconductor device structure includes forming a fin structure over a substrate. The method for forming a semiconductor device structure also includes forming a dummy gate structure across the fin structure. The method for forming a semiconductor device structure also includes forming a first source/drain epitaxial structure beside the dummy gate structure in a first region of the substrate. The method for forming a semiconductor device structure also includes forming a second source/drain epitaxial structure beside the dummy gate structure in a second region of the substrate. The method for forming a semiconductor device structure also includes depositing a spacer layer over the first source/drain epitaxial structure and the second source/drain epitaxial structure. The method for forming a semiconductor device structure also includes recessing the spacer layer, the first source/drain epitaxial structure, and the second source/drain epitaxial structure. The method for forming a semiconductor device structure also includes forming a silicide structure over the first source/drain epitaxial structure and the second source/drain epitaxial structure. The method for forming a semiconductor device structure also includes forming a contact structure over the silicide structure.

In some embodiments, a semiconductor device structure is provided. The semiconductor device structure includes nanostructures formed over a substrate. The semiconductor device structure also includes gate structures wrapped around the nanostructures. The semiconductor device structure also includes source/drain epitaxial structures formed over opposite sides of the nanostructures. The semiconductor device structure also includes a silicide structure formed in the source/drain epitaxial structures. The semiconductor device structure also includes a contact structure formed over the silicide structure. A bottom surface of the silicide structure is lower than a top surface of a bottommost nanostructure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming nanostructures over a substrate;
forming a gate structure wrapped around the nanostructures;
forming source/drain epitaxial structures over opposite sides of the nanostructures;
forming a first interlayer dielectric structure over the source/drain epitaxial structures;
removing the first interlayer dielectric structure;
forming a recess in the source/drain epitaxial structures;
forming a silicide structure in the recess; and
forming a second interlayer dielectric structure over the silicide structure.

2. The method for forming the semiconductor device structure as claimed in claim 1, further comprising:
forming a first etch stop layer over the source/drain epitaxial structures before forming the first interlayer dielectric structure;
etching back the first etch stop layer over the source/drain epitaxial structures; and
forming a second etch stop layer over the silicide structure.

3. The method for forming the semiconductor device structure as claimed in claim 2, wherein the first etch stop layer comprises a first dielectric layer and a second dielectric layer,
wherein the second dielectric layer is removed when etching back the first etch stop layer.

4. The method for forming the semiconductor device structure as claimed in claim 3, wherein the second etch stop layer and the second dielectric layer are made of a same material.

5. The method for forming the semiconductor device structure as claimed in claim 1, further comprising:
forming a spacer layer over the source/drain epitaxial structures and the gate structure after removing the first interlayer dielectric structure; and
etching the spacer layer while forming the recess.

6. The method for forming the semiconductor device structure as claimed in claim 1, further comprising:
implanting dopants in the source/drain epitaxial structures after removing the first interlayer dielectric structure; and
annealing the semiconductor device structure.

7. The method for forming the semiconductor device structure as claimed in claim 6, wherein the dopants are implanted over sidewalls of the source/drain epitaxial structures in the recess.

8. A method for forming a semiconductor device structure, comprising:
forming a fin structure over a substrate;
forming a dummy gate structure across the fin structure;
forming a first source/drain epitaxial structure beside the dummy gate structure in a first region of the substrate;
forming a second source/drain epitaxial structure beside the dummy gate structure in a second region of the substrate;
depositing a spacer layer over the first source/drain epitaxial structure and the second source/drain epitaxial structure;
recessing the spacer layer, the first source/drain epitaxial structure, and the second source/drain epitaxial structure;
forming a silicide structure over the first source/drain epitaxial structure and the second source/drain epitaxial structure; and
forming a contact structure over the silicide structure.

9. The method for forming the semiconductor device structure as claimed in claim 8, further comprising:
forming an isolation material surrounding the fin structure;
recessing the isolation material to form recesses over opposite sides of the dummy gate structure;
forming the first source/drain epitaxial structure in the recess beside the dummy gate structure in the first region of the substrate;
depositing an isolation layer;
forming the second source/drain epitaxial structure in the recess beside the dummy gate structure in the second region of the substrate; and
etching back the isolation layer over the first source/drain epitaxial structure.

10. The method for forming the semiconductor device structure as claimed in claim 9, wherein the first source/drain epitaxial structure is consumed while etching back the isolation layer.

11. The method for forming the semiconductor device structure as claimed in claim 8, further comprising:
forming a first etch stop layer and a first interlayer dielectric structure over the first source/drain epitaxial structure and the second source/drain epitaxial structure;
removing the first interlayer dielectric structure and the first etch stop layer before etching back the isolation layer;
forming a second etch stop layer and a second interlayer dielectric structure over the silicide structure.

12. The method for forming the semiconductor device structure as claimed in claim 11, further comprising:
selectively forming a hard mask layer to expose the first interlayer dielectric structure.

13. The method for forming the semiconductor device structure as claimed in claim 12, wherein the hard mask layer is made of metal.

14. A semiconductor device structure, comprising:
nanostructures formed over a substrate;
gate structures wrapped around the nanostructures;
source/drain epitaxial structures formed over opposite sides of the nanostructures;
a silicide structure formed in the source/drain epitaxial structures;
a contact structure formed over the silicide structure,
wherein a bottom surface of the silicide structure is lower than a top surface of a bottommost nanostructure.

15. The semiconductor device structure as claimed in claim 14, wherein the contact structure protrudes into the silicide structure.

16. The semiconductor device structure as claimed in claim 14, wherein the silicide structure has a tapered sidewall.

17. The semiconductor device structure as claimed in claim 14, wherein the silicide structure comprises a lower portion and an upper portion,
wherein the lower portion of the silicide structure is narrower than the upper portion of the silicide structure.

18. The semiconductor device structure as claimed in claim 17, wherein a sidewall of the upper portion of the silicide structure is more tapered than a sidewall of the lower portion of the silicide structure.

19. The semiconductor device structure as claimed in claim 14, further comprising:
gate spacer layers formed over opposite sides of the gate structures;
a first etch stop layer formed over sidewalls of the gate spacer layers; and
a spacer layer formed over sidewalls of the first etch stop layer.

20. The semiconductor device structure as claimed in claim 14, further comprising:
a first interlayer dielectric structure surrounding the source/drain epitaxial structures;
a second etch stop layer formed over the silicide structure and the first interlayer dielectric structure; and
a second interlayer dielectric structure formed over the second etch stop layer.
